(19) United States
(12) Patent Application Publication
(10) Pub. No.: US 2025/0308862 A1
(43) Pub. Date: Oct. 2, 2025

(54) LEVELING SYSTEMS AND METHODS

(71) Applicant: Applied Materials, Inc., Santa Clara, CA (US)

(72) Inventors: Kaushik ALAYAVALLI, Sunnyvale, CA (US); Amit HATTANGADI, Karnataka (IN); Vishwas BASAVARAJAIAH SOMASHEKAR, Bangalore (IN); Chethan SOMANAHALLI MALLESHAPPA, Bengaluru (IN); Ralph LINDENBERG, Büdingen-Rinderbügen (DE); Selvaprakash PALANISAMY, Karnataka (IN)

(21) Appl. No.: 18/618,956

(22) Filed: Mar. 27, 2024

(51) Int. Cl. H01J 37/32; C23C 16/458; C23C 16/505; H01L 21/687

(52) U.S. Cl. CPC H01J 37/32715; C23C 16/4585; H01J 37/32513; H01L 21/68785; C23C 16/505; H01J 2237/20235; H01J 2237/3321

(57) ABSTRACT

A substrate support of a processing chamber includes a support plate and a seal plate. The processing chamber includes a leveling system configured to raise and lower the support plate and the seal plate. The leveling system is configured to alter an orientation of the seal plate with respect to a chamber component, such as a liner assembly. The leveling system is configured to alter an orientation of the support plate with respect to a chamber component, such as a showerhead.

### BACKGROUND

### Field

Embodiments of the present disclosure generally relate to leveling systems for a substrate support of a substrate processing chamber, such as is used in semiconductor processing or the like.

### Description of the Related Art

Substrate processing chambers, such as those used in semiconductor processing or the like, typically have a substrate support that can be moved vertically between a lowered position and a raised position. The substrate support is moved to the lowered position to facilitate the transfer of a substrate into, and out of, the processing chamber. The substrate support is moved to the raised position to facilitate the processing of a substrate disposed thereon. In some processing chambers, the substrate support includes a support plate and a seal plate. The support plate includes a support surface on which a substrate is disposed for processing. The seal plate is configured to form a seal with another chamber component, such as a liner assembly, when the substrate support is in the raised position.

In some processing chambers, when the substrate support is in the raised position, the substrate and a showerhead of the processing chamber can be misaligned. For example, the substrate might not be parallel with the showerhead because the support surface of the substrate support is not parallel with the showerhead. Such misalignment can result in uneven processing of the substrate, which adversely affects product quality and yield.

In some processing chambers, when the substrate support is in the raised position, the seal between the seal plate and the chamber component can be compromised by misalignment of the seal plate with respect to the chamber component. The compromised seal can result in a waste of processing gases or the deposition of contaminants in various regions of the processing chamber. There is a need for improved systems that address such problems.

### SUMMARY

The present disclosure generally relates to leveling systems for a substrate support of a substrate processing chamber, such as is used in semiconductor processing or the like. In one implementation, a leveling system includes an adapter plate configured for coupling to a base of a processing chamber. A frame is coupled to the adapter plate by a plurality of leveling units, and a lift guide is coupled to the frame. A carrier plate is movable along the lift guide between a lowered position and a raised position.

In another implementation, a method of operating a processing chamber includes moving a seal plate of a substrate support in the processing chamber towards a liner assembly. The method further includes adjusting at least one of a plurality of first leveling units to change an orientation of the seal plate with respect to the liner assembly. The method further includes adjusting at least one of a plurality of second leveling units to change an orientation of a support plate of the substrate support with respect to the seal plate.

In another implementation, a processing chamber includes a chamber body including a base. A substrate support is disposed within the chamber body, the substrate support including a seal plate disposed below a support plate. A first shaft is coupled to the seal plate. The first shaft extends through the base. A second shaft is coupled to the support plate. The second shaft extends through the base. The processing chamber further includes a leveling system. The leveling system includes an adapter plate coupled to the base. A frame is coupled to the adapter plate by a plurality of leveling units, and a lift guide is coupled to the frame. A carrier plate is movable along the lift guide between a lowered position and a raised position. The carrier plate coupled to the first shaft.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1A is a schematic view of a processing chamber in which a substrate support is in a lowered position.

FIG. 1B is a schematic view of the processing chamber of FIG. 1A in which the substrate support is in a raised position for the processing of a substrate.

FIG. 2 schematically illustrates a leveling system for use with the processing chamber of FIGS. 1A and 1B.

FIG. 3 schematically illustrates a portion of the leveling system of FIG. 2.

FIGS. 4A, 4B, and 4C schematically illustrate exemplary components of the leveling system of FIG. 2.

FIGS. 5A, 5B, 5C, and 5D schematically illustrate exemplary operations of the leveling system of FIG. 2.

FIG. 6 is a flow diagram of a method of operating a processing chamber incorporating a leveling system, such as the leveling system of FIG. 2.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure concerns leveling systems for a substrate support of a substrate processing chamber, such as is used in semiconductor processing or the like. In some embodiments, the leveling systems facilitate the orientation of a seal plate of a substrate support such that a seal can be formed between the seal plate and another chamber component, such as a liner assembly. In some embodiments, the leveling systems facilitate the orientation of a support plate of a substrate support such that a substrate disposed on the support plate is parallel with a showerhead. In some embodiments, the orientation of the support plate and the orientation of the seal plate are adjusted simultaneously. In some embodiments, the orientation of the support plate can be adjusted independently of the orientation of the seal plate.

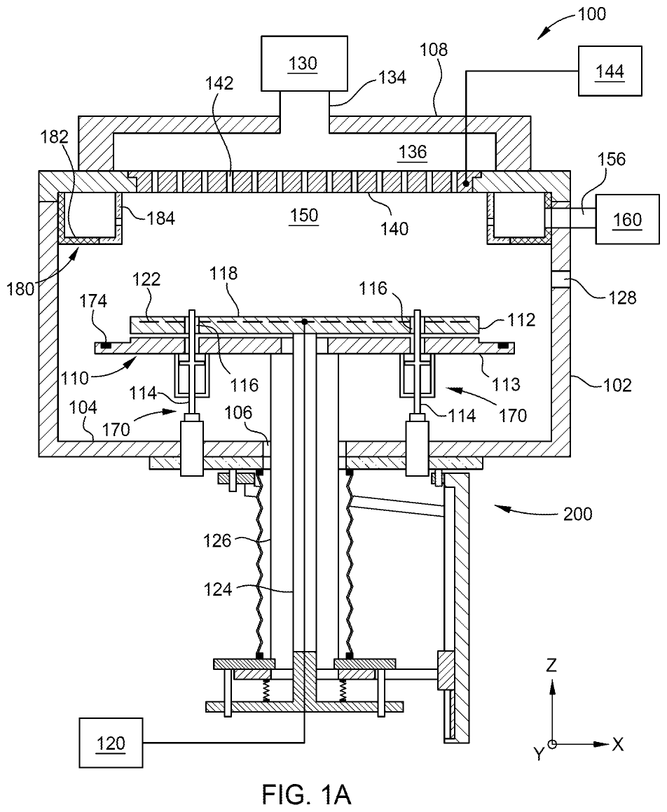

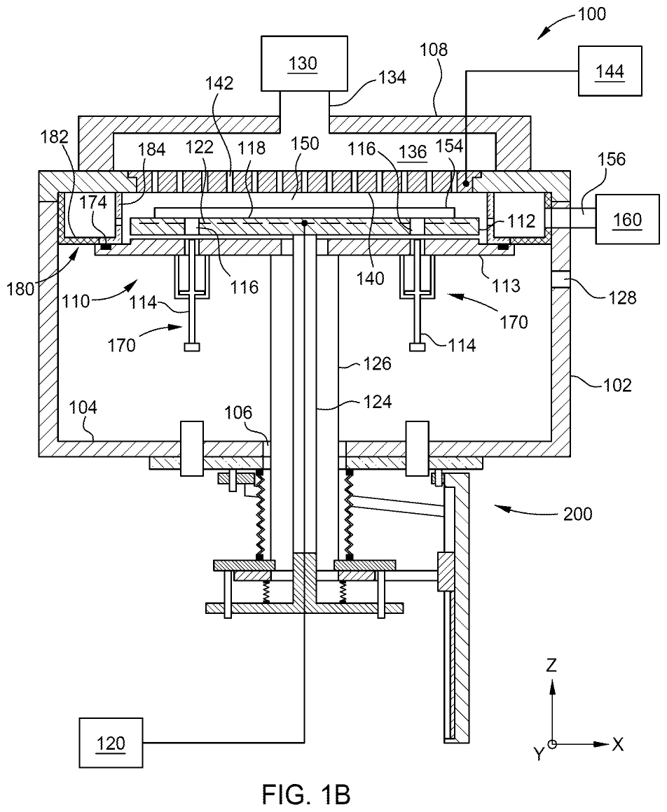

FIGS. 1A and 1B are schematic cross-sectional views of a processing chamber 100. In general, the processing chamber 100 can include an atomic layer deposition (ALD) chamber, chemical vapor deposition (CVD) chamber, physical vapor deposition (PVD) chamber, etch chamber, degas chamber, an ion implantation chamber, ashing chamber, cleaning chamber, a thermal processing chamber (e.g., rapid thermal processing, anneal, cool down, thermal management control), or other type of substrate processing chamber.

However, as illustrated in FIGS. 1A and 1B, the processing chamber 100 is configured as a Plasma Enhanced Chemical Vapor Deposition (“PECVD”) chamber. Nevertheless, the processing chamber 100 may be configured to perform one or more other processing operations that may or may not involve a plasma. The processing chamber 100 may include relevant hardware associated with any of the above processes.

The processing chamber 100 includes a chamber body 102 with a base 104, a substrate support 110 disposed inside the chamber body 102, and a lid 108 coupled to the chamber body 102. FIG. 1A shows the substrate support 110 in a lowered position, such as when a substrate is transferred into or out of the processing chamber 100. FIG. 1B shows the substrate support 110 in a raised position, such as when a substrate is being processed. In some embodiments the processing chamber 100 includes a showerhead 140. In some of such embodiments, the showerhead 140 can serve as an electrode, and is coupled to a power source 144 through a match circuit (not shown). The power source 144 is a radio frequency (RF) power source that is electrically coupled to the electrode. Further, the power source 144 provides between about 100 Watts and about 3,000 Watts at a frequency of about 50 KHz to about 15 MHz. In some embodiments, the power source 144 can be pulsed during various operations. The electrode and power source 144 facilitate control of a plasma formed within a processing volume 150.

The showerhead 140 features openings 142 for admitting a process gas or gases into the processing volume 150 from a gas supply source 130. The process gases are supplied to the processing chamber 100 via a gas feed 134, and the process gases enter a plenum 136 prior to flowing through the openings 142. In some embodiments, different process gases that are flowed simultaneously during a processing operation enter the processing chamber 100 via separate gas feeds and separate plenums prior to entering the processing volume 150 through the showerhead 140.

The gas supply source 130 includes one or more gas sources. The gas supply source 130 is configured to deliver the one or more gases from the one or more gas sources through the showerhead 140 and into the processing volume 150. Each of the one or more gas sources provides a process gas such as silane, disilane, tetraethyl orthosilicate (TEOS), germane, a metal halide (such as titanium tetrachloride, tantalum pentachloride, tungsten hexafluoride), an organometallic (such as tetrakis (dimethylamido) titanium, pentakis (dimethylamido) tantalum), ammonia, oxygen (O₂), hydrogen peroxide, hydrogen, diborane, chlorine (Cl₂), sulfur hexafluoride, a hydrocarbon (generically CₓH_{y}), among others. In some embodiments, the process gas may be ionized to form a plasma within the processing volume 150. In an example, one or more of a carrier gas and an ionizable process gas are provided into the processing volume 150 to process a substrate 154 (FIG. 1B). For instance, when processing a 300 mm substrate, the process gases are introduced to the processing chamber 100 at a flow rate from about 6500 sccm to about 8000 sccm, from about 100 sccm to about 10,000 sccm, or from about 100 sccm to about 1000 sccm. Alternatively, other flow rates may be utilized. In some examples, a remote plasma source can be used to deliver plasma to the processing chamber 100 and can be coupled to the gas supply source 130.

In some embodiments, the processing chamber 100 includes a physical vapor deposition (PVD) target, which is similarly positioned as the showerhead 140 illustrated in FIGS. 1A and 1B, and thus takes the place of the showerhead 140. In such a configuration, the PVD target serves as a sputtering material source, and is coupled to the power source 144, which is typically a DC power source. The DC power source is adapted to provide a DC voltage at a power level that is typically greater than 1 kW. A magnetron (e.g., magnet assembly not shown) is positioned behind the PVD target and is used to help control the gas ion bombardment of the lower surface of the target during processing to allow for the uniform erosion (e.g., sputtering) of the target surface during processing.

In some embodiments, the processing chamber 100 includes a liner assembly 180. In some embodiments, the liner assembly 180 includes one or more liners 182. In some embodiments, the liner assembly 180 includes a pumping ring 184. Process gases flow into the processing volume 150 through the showerhead 140, then exit the processing volume 150 via the liner assembly 180. The process gases flow from the liner assembly 180 through an exhaust port 156 coupled to a vacuum pump 160. The vacuum pump 160 removes excess process gases or by-products from the processing volume 150 via the exhaust port 156 during and/or after processing the substrate 154.

The substrate 154 is provided to the processing volume 150 through an opening 128. In an example, the substrate 154 is transported into or out of the processing volume 150 using a carrier, such as a blade, that is conveyed by a robotic arm. In another example, the substrate 154 is transported into or out of the processing volume 150 using a carrier that is conveyed by magnetic levitation.

In either or any of the various possible processing chamber configurations, the substrate support 110 includes a support plate 112 that includes a support surface 118 configured to support the substrate 154 in the processing volume 150 of the processing chamber 100 during processing. In some embodiments that may be combined with other embodiments, the support plate 112 is coupled to a seal plate 113. In some examples, a lower surface of the support plate 112 is coupled to an upper surface of the seal plate 113. As illustrated, in other examples, the lower surface of the support plate 112 and the upper surface of the seal plate 113 are separated by a gap. In some embodiments that may be combined with other embodiments, the seal plate 113 is present, but is not coupled directly to the support plate 112. In some embodiments, the seal plate 113 may be omitted.

In some embodiments that may be combined with other embodiments, one or more seal members 174 are disposed in a peripheral upward-facing surface of the seal plate 113. In some embodiments that may be combined with other embodiments, the one or more seal members 174 includes an o-ring, an x-ring, a lip seal, or a labyrinth seal. In some embodiments that may be combined with other embodiments, the one or more seal members 174 includes an RF gasket.

In some embodiments that may be combined with other embodiments, when the substrate support 110 is in the raised position (such as shown in FIG. 1B), the one or more seal members 174 form a seal against the liner assembly 180. In an example, the one or more seal members 174 form a seal against the liner 182. In another example, the one or more seal members 174 form a seal against the pumping ring 184.

In some embodiments that may be combined with other embodiments, when the substrate support 110 is in the raised position, the one or more seal members 174 hinder passage of plasma across an interface between the seal plate 113 and the liner assembly 180. In an example, the one or more seal members 174 hinder passage of plasma across an interface between the seal plate 113 and the liner 182. In another example, the one or more seal members 174 hinder passage of plasma across an interface between the seal plate 113 and the pumping ring 184.

The support plate 112 contains, or is formed from, one or more metallic or ceramic materials. Exemplary metallic or ceramic materials include one or more metals, metal oxides, metal nitrides, metal oxynitrides, or any combination thereof. For example, the support plate 112 may contain or be formed from aluminum, aluminum oxide, aluminum nitride, aluminum oxynitride, or any combination thereof.

As illustrated, an electrode 122 is embedded within the support plate 112, but alternatively may be coupled to a surface (such as support surface 118) of the support plate 112. The electrode 122 is coupled to a power source 120. It is contemplated that the power source 120 may supply DC power, pulsed DC power, radio frequency (RF) power, pulsed RF power, or any combination thereof. The power source 120 is configured to drive the electrode 122 with a drive signal to generate a plasma within the processing volume 150. It is contemplated that the drive signal may be one of a DC signal and a varying voltage signal (e.g., RF signal). Further, the electrode 122 may alternatively be coupled to the power source 144 instead of the power source 120, and the power source 120 may be omitted.

In some embodiments that may be combined with other embodiments, the electrode 122 may be omitted. In some embodiments that may be combined with other embodiments, the electrode 122 (or another electrode in the support plate 112) is configured as a chucking electrode. In some embodiments that may be combined with other embodiments, the support plate 112 includes a heater, such as a resistive heating element. In some embodiments that may be combined with other embodiments, the substrate support 110 includes one or more coolant channels.

It is contemplated that the processing chamber 100 contains three lift pins 114, but may contain more than three lift pins 114, such as four, five, six, or more lift pins 114. Each lift pin 114 is disposed through a corresponding hole 116 in the substrate support 110, and is moveable to lift the substrate 154 off the support surface 118 to facilitate transfer of the substrate 154 into and out of the processing chamber 100. In some embodiments that may be combined with other embodiments, each lift pin 114 is actuated by a corresponding lift pin system 170.

The support plate 112 is disposed on a support shaft 124 that extends through an aperture 106 in the base 104 of the processing chamber 100. In some embodiments that may be combined with other embodiments, the support plate 112 is rotated by a drive mechanism (not shown) coupled to the support shaft 124 while the substrate 154 is undergoing processing in the processing chamber 100. Movement of the support shaft 124 (e.g., along the Z axis) raises or lowers the support plate 112 such that the support surface 118 is moved towards or away from the showerhead 140 (or the PVD target, if present).

The seal plate 113 is disposed on a support shaft 126 that extends through the aperture 106 in the base 104 of the processing chamber 100. The support shaft 124 is disposed through the support shaft 126. Movement of the support shaft 126 (e.g., along the Z axis) raises or lowers the seal plate 113 such that the seal member 174 of the seal plate 113 is moved towards or away from the liner assembly 180.

The support shaft 124 and the support shaft 126 are coupled to a leveling system 200. The leveling system 200 raises and lowers the support shaft 124 and the support shaft 126 (e.g., along the Z axis), and so raises and lowers the support plate 112 and the seal plate 113.

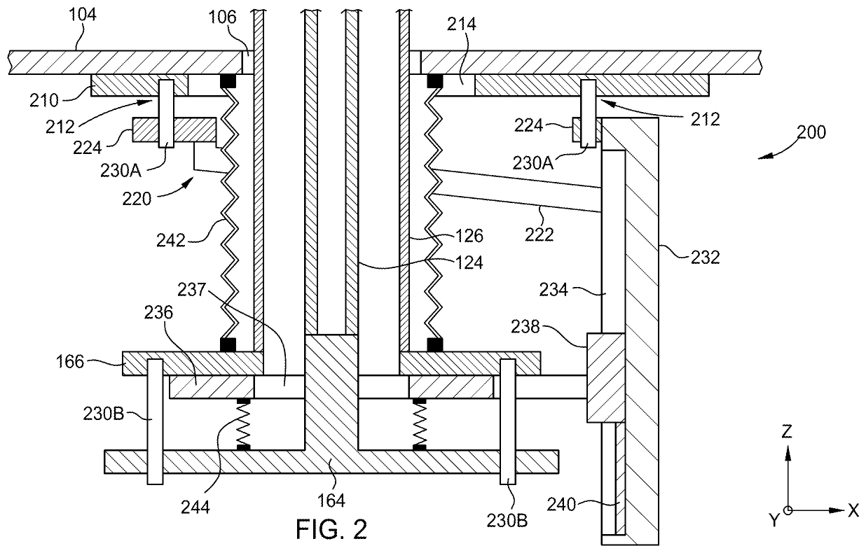

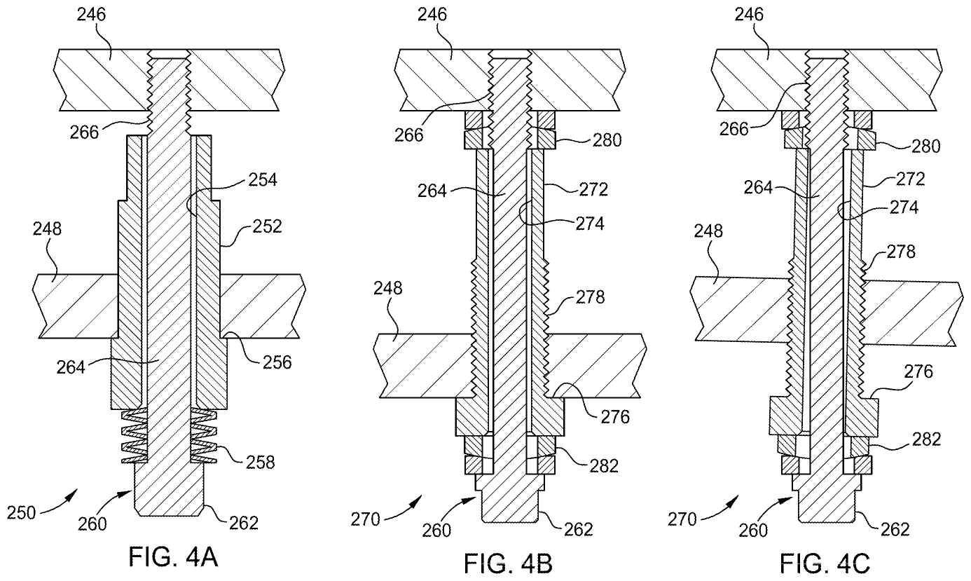

FIG. 2 schematically illustrates the leveling system 200. The leveling system 200 includes an adapter plate 210. In use, the adapter plate 210 is coupled to an underside of the base 104 of the processing chamber 100, such as by bolts. A frame 220 is coupled to the adapter plate 210 at a plurality of attachment locations 212 of the adapter plate 210. In some embodiments that may be combined with other embodiments, the frame 220 is coupled to the adapter plate 210 at three attachment locations 212 of the adapter plate 210. The frame 220 is coupled to the adapter plate 210 at each attachment location 212 by a corresponding leveling unit 230A (described below with respect to FIGS. 4A to 4C). Each leveling unit 230A is adjustable to change a distance between the adapter plate 210 and the frame 220 at each attachment location 212 of the adapter plate 210.

A lift guide 232 is coupled to the frame 220. The lift guide 232 includes a guide channel 234. A carrier plate 236 is movable along the lift guide 232. The carrier plate 236 is coupled to a carriage 238 that is movable along the guide channel 234. An actuator 240, such as a piston or a linear motor, moves the carriage 238 along the guide channel 234. Movement of the carriage 238 (e.g., along the Z axis) along the guide channel 234 moves the carrier plate 236 along the lift guide 232 between a lowered position and a raised position.

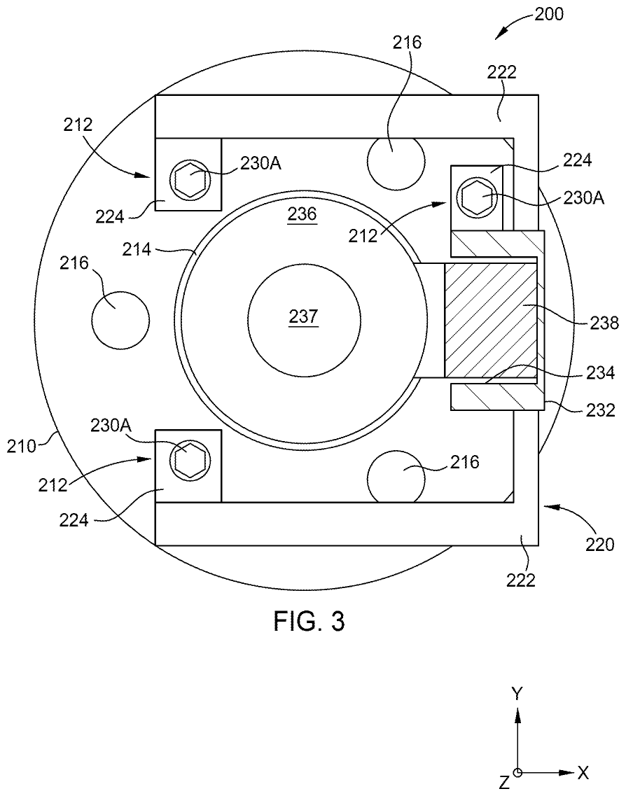

FIG. 3 schematically illustrates a portion of the leveling system 200 viewed from below. The frame 220 includes one or more arms 222 and flanges 224 coupled to the lift guide 232. Each leveling unit 230A is coupled to the frame 220 at a corresponding flange 224. It is contemplated that the frame 220 may take other forms. The adapter plate 210 includes an aperture 214, through which the support shaft 124 and the support shaft 126 extend. The attachment locations 212, where the leveling units 230A are coupled to the adapter plate 210, are spaced around the aperture 214. In some embodiments that may be combined with other embodiments, the adapter plate 210 includes one or more secondary apertures 216. When installed on the base 104 of the processing chamber 100, the one or more secondary apertures 216 accommodate, and/or provide access to, corresponding lift pin systems (170, FIGS. 1A, 1B).

An orientation of the lift guide 232 with respect to the adapter plate 210 is adjustable. As described below, adjustment of one or more of the leveling units 230A changes the positioning of the frame 220 and the lift guide 232 coupled thereto with respect to the adapter plate 210.

Returning to FIG. 2, the support shaft 126 is coupled to the carrier plate 236. In some embodiments that may be combined with other embodiments, the support shaft 126 is coupled to the carrier plate 236 via a seal plate hub 166 that is coupled to the support shaft 126. In an example, the seal plate hub 166 provides connections for the passage of a coolant to and from the seal plate 113. The seal plate hub 166 is coupled to an upper surface of the carrier plate 236, such as by bolts.

The carrier plate 236 includes an aperture 237, through which the support shaft 124 extends. The support shaft 124 is coupled to a support plate hub 164. In an example, the support plate hub 164 provides connections for the passage of a coolant to and from the support plate 112. The support plate hub 164 is disposed below the seal plate hub 166 and below the carrier plate 236. The support plate hub 164 is coupled to the seal plate hub 166 by a plurality of leveling units 230B (described below with respect to FIGS. 4A to 4C). In some embodiments that may be combined with other embodiments, the support plate hub 164 is coupled to the seal plate hub 166 by three leveling units 230B. The leveling units 230B are spaced around the aperture 237 of the carrier plate 236.

Movement of the carrier plate 236 along the lift guide 232 between a lowered position and a raised position moves the seal plate hub 166, the support shaft 126, the seal plate (113, FIGS. 1A, 1B), the support plate hub 164, the support shaft 124, and the support plate (112, FIGS. 1A, 1B) between lowered and raised positions.

An orientation of the support shaft 124 with respect to the support shaft 126 is adjustable. As described below, adjustment of one or more of the leveling units 230B changes the positioning of the support plate hub 164 and the support shaft 124 coupled thereto with respect to the seal plate hub 166 and the support shaft 126 coupled thereto.

In some embodiments that may be combined with other embodiments, a bellows 242 surrounds the support shaft 126 and extends between the seal plate hub 166 and the base 104 of the processing chamber 100. In some embodiments that may be combined with other embodiments, a bellows 244 surrounds the support shaft 124 and extends between the support plate hub 164 and the carrier plate 236. The bellows 242 and the bellows 244 provide isolation of the environment within the processing chamber 100 from the ambient environment external to the processing chamber 100.

FIGS. 4A to 4C schematically illustrate exemplary embodiments of leveling unit 230A and leveling unit 230B. FIG. 4A depicts leveling unit 250, which can represent leveling unit 230A or leveling unit 230B. When leveling unit 250 represents leveling unit 230A, an upper plate 246 in the Figure corresponds to the adapter plate 210, and a lower plate 248 in the Figure corresponds to a flange 224 of the frame 220. When leveling unit 250 represents leveling unit 230B, upper plate 246 corresponds to the seal plate hub 166, and lower plate 248 corresponds to the support plate hub 164.

Leveling unit 250 includes a sleeve 252 disposed through the lower plate 248. A fastener 260, such as a bolt, is disposed through the sleeve 252, and penetrates into the upper plate 246. The fastener 260 is fixed to the upper plate 248, such as by a thread 266. The lower plate 248 rests on a shoulder 256 of the sleeve 252. The weight of the lower plate 248 and components attached thereto is transferred to the sleeve 252 and to a head 262 of the fastener 260.

Adjustment of the leveling unit 250 changes a vertical position (e.g., along the Z axis) of the lower plate 248 with respect to the upper plate 246. The leveling unit 250 is adjusted by inserting or removing one or more shims 258 between the sleeve 252 and the head 262 of the fastener 260.

In situations in which each leveling unit 250 of a set of leveling units 250 is subject to the same amount of adjustment, the lower plate 248 is raised or lowered without changing an orientation of the lower plate 248 with respect to the upper plate 246. In an example, the lower plate 248 and upper plate 246 are parallel with each other before and after adjustment of each leveling unit 250. In situations in which a leveling unit 250 is subject to a different amount of adjustment than other leveling units 250 of a set of leveling units 250, the lower plate 248 is raised or lowered such that an orientation of the lower plate 248 with respect to the upper plate 246 is changed. In an example, the lower plate 248 and upper plate 246 are parallel with each other before adjustment of one or more leveling unit 250, but not parallel with each other after adjustment of one or more each leveling unit 250. Clearance between an inner wall 254 of the sleeve 252 and a shank 264 of the fastener 260 accommodates lateral and/or angular displacement of the sleeve 252 with respect to the fastener 260 resulting from adjustment of the leveling unit 250. Angular displacement of the sleeve 272 with respect to the fastener 260 is accommodated also by the shim 258.

FIGS. 4B and 4C depict leveling unit 270, which can represent leveling unit 230A or leveling unit 230B. When leveling unit 270 represents leveling unit 230A, upper plate 246 corresponds to the adapter plate 210, and lower plate 248 corresponds to a flange 224 of the frame 220. When leveling unit 270 represents leveling unit 230B, upper plate 246 corresponds to the seal plate hub 166, and lower plate 248 corresponds to the support plate hub 164.

Leveling unit 270 includes a sleeve 272 disposed through the lower plate 248. The sleeve 272 is coupled to the lower plate 248 by a thread 278. The fastener 260 is disposed through the sleeve 272, and penetrates into the upper plate 246. The fastener 260 is fixed to the upper plate 246, such as by the thread 266. In some embodiments, the lower plate 248 is suspended by attachment to the thread 278 of the sleeve 272. In some embodiments, the lower plate 248 rests on a shoulder 276 of the sleeve 272. The weight of the lower plate 248 and components attached thereto is transferred to the sleeve 252 and to the head 262 of the fastener 260. A spherical washer 280 is disposed around the fastener 260 between the sleeve 272 and the upper plate 246. As illustrated, in some embodiments, a spherical washer 282 is disposed around the fastener 260 between the sleeve 272 and the head 262 of the fastener 260. In some embodiments, the spherical washer 282 is omitted.

Adjustment of the leveling unit 270 changes a vertical position (e.g., along the Z axis) of the lower plate 246 with respect to the upper plate 248. The leveling unit 270 is adjusted by rotating the sleeve 272 with respect to the lower plate 248. Rotation of the sleeve 272 causes the lower plate 248 to travel along the thread 278.

In situations in which each leveling unit 270 of a set of leveling units 270 is subject to the same amount of adjustment, the lower plate 248 is raised or lowered without changing an orientation of the lower plate 248 with respect to the upper plate 246. In an example, the lower plate 248 and upper plate 246 are parallel with each other before and after adjustment of each leveling unit 270. In situations in which a leveling unit 270 is subject to a different amount of adjustment than other leveling units 270 of a set of leveling units 270, the lower plate 248 is raised or lowered such that an orientation of the lower plate 248 with respect to the upper plate 246 is changed. In an example, the lower plate 248 and upper plate 246 are parallel with each other before adjustment of one or more leveling unit 270, but not parallel with each other after adjustment of one or more each leveling unit 270.

FIG. 4B shows the lower plate 248 in a lower position. The lower plate 248 is parallel with the upper plate 246. FIG. 4C shows the lower plate 248 raised closer to the upper plate 246 and with a change in the orientation of the lower plate 248 with respect to the upper plate 248. In FIG. 4C, the lower plate 248 is not parallel with the upper plate 246. Clearance between an inner wall 274 of the sleeve 272 and the shank 264 of the fastener 260 accommodates lateral and/or angular displacement of the sleeve 272 with respect to the fastener 260 resulting from adjustment of the leveling unit 270. Angular displacement of the sleeve 272 with respect to the fastener 260 is accommodated also by the spherical washer 280 and/or the spherical washer 282.

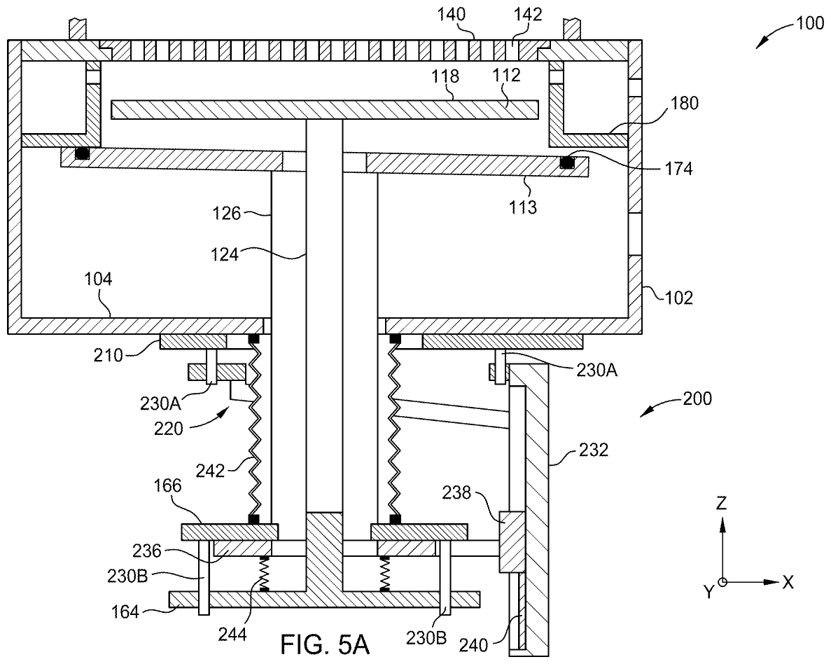

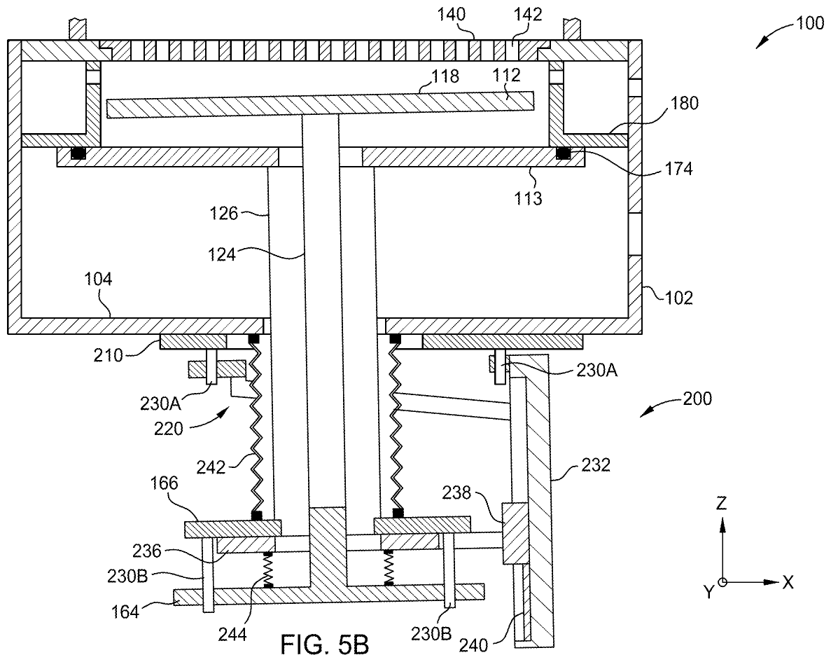

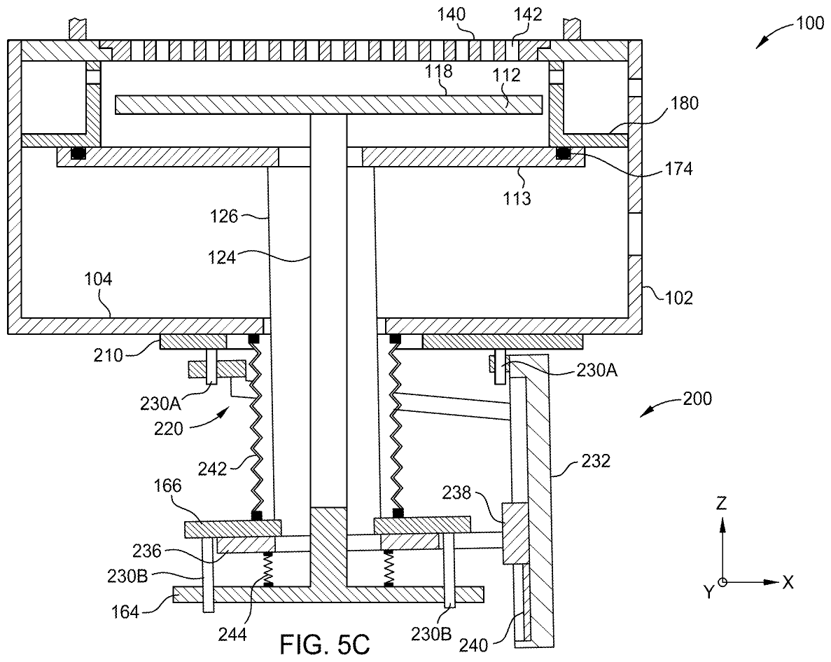

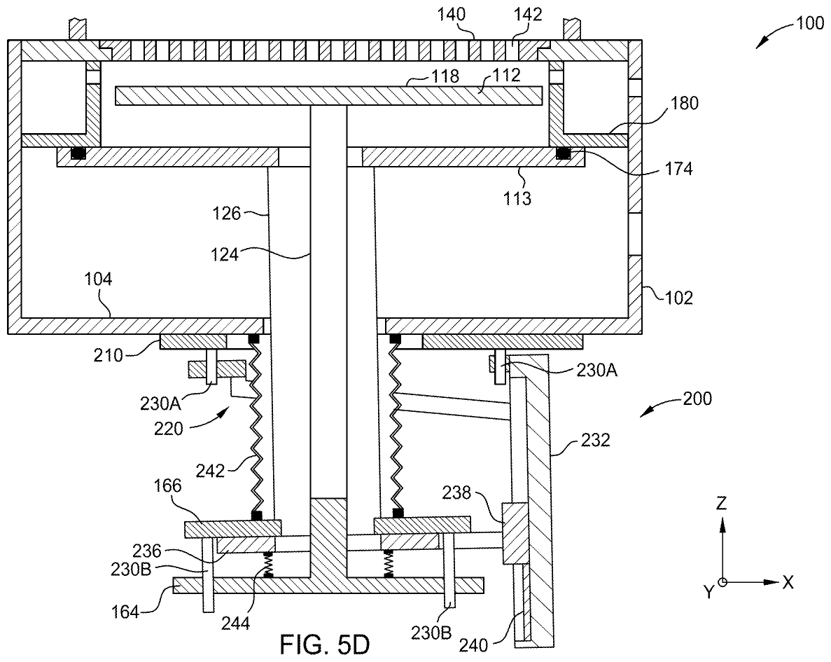

FIGS. 5A to 5D schematically illustrate a sequence of exemplary operations of the leveling system 200. In FIG. 5A, the carrier plate 236 has raised the support plate 112 and the seal plate 113 to the liner assembly 180 in the processing chamber 100. The seal plate 113 is shown to be incorrectly positioned with respect to the liner assembly 180. In the illustrated example, the seal plate 113 is disposed at an acute angle to the liner assembly 180, and the seal member 174 does not contact the liner assembly 180.

FIG. 5B shows the outcome of a first leveling operation of the leveling system 200. The first leveling operation includes adjusting at least one leveling unit 230A of the set of leveling units 230A coupling the adapter plate 210 to the frame 220 of the leveling system. Adjusting the at least one leveling unit 230A alters an orientation of the frame 220 and the lift guide 232 with respect to the adapter plate 210. The adapter plate 210 remains stationary. The carrier plate 236 moves with the lift guide 232. The seal plate hub 166, support plate hub 164, support shaft 124, support shaft 126, seal plate 113 and support plate 112 move with the carrier plate 236. The orientation of the seal plate 113 with respect to the liner assembly 180 (and to the showerhead 140) is altered as a result of adjusting the at least one leveling unit 230A. The orientation of the support plate 112 with respect to the liner assembly 180 (and to the showerhead 140) is altered as a result of adjusting the at least one leveling unit 230A.

The first leveling operation places the seal plate 113 in a position with respect to the liner assembly 180 such that the seal member 174 contacts the liner assembly 180 and seals an interface between the liner assembly 180 and the seal plate 113.

In some embodiments that may be combined with other embodiments, the first leveling operation is omitted. In an example, the seal member 174 may contact the liner assembly 180 and seal an interface between the liner assembly 180 and the seal plate 113 when the seal plate 113 is raised, without necessitating the first leveling operation.

As illustrated, in some embodiments that may be combined with other embodiments, a correction is required to an orientation of the support plate 112 with respect to the showerhead 140. In the illustrated example, the support surface 118 of the support plate 112 is not parallel with the showerhead 140. The required correction may be achieved by a second leveling operation of the leveling system 200.

FIG. 5C shows the outcome of the second leveling operation of the leveling system 200. The second leveling operation includes adjusting at least one leveling unit 230B of the set of leveling units 230B coupling the seal plate hub 166 to the support plate hub 164. Adjusting the at least one leveling unit 230B alters an orientation of the support plate hub 164 with respect to seal plate hub 166. The seal plate hub 166, support shaft 126, and seal plate 113 remain stationary. The support shaft 124 and the support plate 112 move with the support plate hub 164. The orientation of the support plate 112 with respect to the seal plate 113 is altered as a result of adjusting the at least one leveling unit 230B. The orientation of the support plate 112 with respect to the showerhead 140 is altered as a result of adjusting the at least one leveling unit 230B. In the illustrated example, the support surface 118 of the support plate 112 is altered to be parallel with the showerhead 140.

In some embodiments that may be combined with other embodiments, the second leveling operation is omitted. In an example, the support surface 118 of the support plate 112 may be parallel with the showerhead 140 when the seal plate 113 is raised, without necessitating the second leveling operation. In another example, the support surface 118 of the support plate 112 may be parallel with the showerhead 140 after the first levelling operation, without necessitating the second leveling operation.

As illustrated, in some embodiments that may be combined with other embodiments, a correction is required to an elevation of the support plate 112 with respect to the showerhead 140 after the seal plate is raised towards the liner assembly or after the first leveling operation, or after the second leveling operation. In the illustrated example, the support surface 118 of the support plate 112 is not close enough to the showerhead 140. The required correction may be achieved by a third leveling operation of the leveling system 200.

FIG. 5D shows the outcome of the third leveling operation of the leveling system 200. The third leveling operation includes adjusting each leveling unit 230B of the set of leveling units 230B coupling the seal plate hub 166 to the support plate hub 164. Each leveling unit 230B is adjusted by a similar degree such that the support plate hub 164, support shaft 124, and support plate 112 are raised while maintaining the support surface 118 parallel with the showerhead 140. The seal plate hub 166, support shaft 126, and seal plate 113 remain stationary.

In another example, the support surface of the support plate is too close to the showerhead, and the third leveling operation includes adjusting each leveling unit such that the support plate hub, support shaft, and support plate are lowered while maintaining the support surface parallel with the showerhead.

In some embodiments that may be combined with other embodiments, the third leveling operation is omitted. In an example, the support surface 118 of the support plate 112 is placed at a desired distance from the showerhead 140 when the seal plate 113 is raised, without necessitating the third leveling operation. In another example, the support surface 118 of the support plate 112 is placed at a desired distance from the showerhead 140 after the first levelling operation, without necessitating the third leveling operation. In another example, the support surface 118 of the support plate 112 is placed at a desired distance from the showerhead 140 after the second levelling operation, without necessitating the third leveling operation.

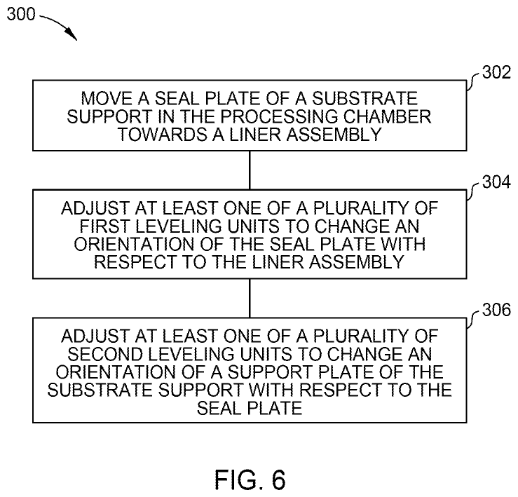

FIG. 6 is a flow diagram of a method 300 of operating a processing chamber, such as processing chamber 100. The processing chamber incorporates a leveling system, such as leveling system 200. In some embodiments that may be combined with other embodiments, the method 300 is performed using any of the apparatus, systems, or processes of the present disclosure.

Operation 302 includes moving a seal plate of a substrate support in the processing chamber towards a liner assembly. In an example, the seal plate is raised using a carrier plate (such as carrier plate 236).

Operation 304 includes adjusting at least one of a plurality of first leveling units to change an orientation of the seal plate with respect to the liner assembly. In some embodiments that may be combined with other embodiments, the at least one of the plurality of first leveling units are configured similarly to leveling unit 250. In some examples, adjusting the at least one of the plurality of first leveling units includes installing a shim between a head of a fastener and a sleeve of the at least one of the plurality of first leveling units. In some embodiments that may be combined with other embodiments, the at least one of the plurality of first leveling units are configured similarly to leveling unit 270. In some examples, adjusting the at least one of the plurality of first leveling units includes rotating a sleeve with respect to a frame of the leveling system.

In some embodiments that may be combined with other embodiments, adjusting the at least one of the plurality of first leveling units changes the orientation of the support plate with respect to a showerhead of the processing chamber. In some embodiments that may be combined with other embodiments, adjusting the at least one of the plurality of first leveling units is performed while an interior of the processing chamber is at a temperature less than a temperature of a processing operation.

In some embodiments that may be combined with other embodiments, method 300 includes engaging the liner assembly with a seal coupled to the seal plate after operation 304.

Operation 306 includes adjusting at least one of a plurality of second leveling units to change an orientation of a support plate of the substrate support with respect to the seal plate. In some embodiments that may be combined with other embodiments, the at least one of the plurality of second leveling units are configured similarly to leveling unit 250. In some examples, adjusting the at least one of the plurality of second leveling units includes installing a shim between a head of a fastener and a sleeve of the at least one of the plurality of second leveling units. In some embodiments that may be combined with other embodiments, the at least one of the plurality of second leveling units are configured similarly to leveling unit 270. In some examples, adjusting the at least one of the plurality of second leveling units includes rotating the sleeve with respect to a support plate hub that is coupled to the support plate via a support shaft.

In some embodiments that may be combined with other embodiments, adjusting the at least one of the plurality of second leveling units changes the orientation of the support plate with respect to the showerhead of the processing chamber. In some embodiments that may be combined with other embodiments, the orientation of the seal plate with respect to the liner assembly is maintained while adjusting the at least one of the plurality of second leveling units. In some embodiments that may be combined with other embodiments, adjusting the at least one of the plurality of second leveling units is performed while an interior of the processing chamber is at a temperature corresponding to a temperature of a processing operation.

In some embodiments that may be combined with other embodiments, method 300 includes lowering the seal plate and the substrate support after operation 306. In some embodiments that may be combined with other embodiments, method 300 includes placing a substrate on the substrate support. In some embodiments that may be combined with other embodiments, method 300 includes raising the seal plate, the substrate support, and the substrate until a seal on the seal plate engages a liner assembly in the processing chamber. In some embodiments that may be combined with other embodiments, method 300 includes performing a processing operation on the substrate in the processing chamber.

In some embodiments that may be combined with other embodiments, method 300 includes repeating operation 304 after processing one or more substrates in the processing chamber. In some embodiments that may be combined with other embodiments, method 300 includes repeating operation 306 after processing one or more substrates in the processing chamber.

In some embodiments that may be combined with other embodiments, method 300 includes centering the substrate support in the processing chamber before operation 304. In an example, centering the substrate support is performed using a centering jig. In some embodiments that may be combined with other embodiments, method 300 includes verifying the centering of the substrate support after operation 306.

Embodiments of the present disclosure facilitate the positioning and orientation of a seal plate of a substrate support to promote the creation of a seal between the seal plate and a chamber component, such as liner assembly. Embodiments of the present disclosure facilitate the positioning and orientation of a support plate of a substrate support to promote the alignment of a substrate on the support plate with a showerhead.

It is contemplated that any one or more elements or features of any one disclosed embodiment may be beneficially incorporated in any one or more other non-mutually exclusive embodiments. While the foregoing is directed to embodiments of the present disclosure, other and further embodiments of the disclosure may be devised without departing from the basic scope thereof, and the scope thereof is determined by the claims that follow.

What is claimed is:

1. A leveling system, comprising:
an adapter plate configured for coupling to a base of a processing chamber;
a frame coupled to the adapter plate by a plurality of leveling units;
a lift guide coupled to the frame; and
a carrier plate movable along the lift guide between a lowered position and a raised position.

2. The leveling system of claim 1, wherein each of the leveling units includes:
a sleeve coupled to the frame;
a fastener disposed through the sleeve and penetrating into the adapter plate; and
a shim disposed between a head of the fastener and the adapter plate.

3. The leveling system of claim 1, wherein each of the leveling units includes:
a sleeve coupled to the frame by a thread; and
a fastener disposed through the sleeve and penetrating into the adapter plate.

4. The leveling system of claim 1, wherein an orientation of the lift guide with respect to the adapter plate is altered by adjusting one or more of the leveling units.

5. A method of operating a processing chamber, comprising:
moving a seal plate of a substrate support in the processing chamber towards a liner assembly;
adjusting at least one of a plurality of first leveling units to change an orientation of the seal plate with respect to the liner assembly; and
adjusting at least one of a plurality of second leveling units to change an orientation of a support plate of the substrate support with respect to the seal plate.

6. The method of claim 5, further comprising engaging the liner assembly with a seal coupled to the seal plate after adjusting the at least one of the plurality of first leveling units.

7. The method of claim 5, wherein adjusting the at least one of the plurality of first leveling units changes the orientation of the support plate with respect to a showerhead.

8. The method of claim 7, wherein adjusting the at least one of the plurality of second leveling units changes the orientation of the support plate with respect to the showerhead.

9. The method of claim 8, wherein the orientation of the seal plate with respect to the liner assembly is maintained while adjusting the at least one of the plurality of second leveling units.

10. The method of claim 5, wherein adjusting the at least one of the plurality of first leveling units is performed while an interior of the processing chamber is at a temperature less than a temperature of a processing operation.

11. The method of claim 5, wherein adjusting the at least one of the plurality of second leveling units is performed while an interior of the processing chamber is at a temperature corresponding to a temperature of a processing operation.

12. The method of claim 5, wherein:
the at least one of the plurality of the first leveling units includes:
a sleeve coupled to a frame; and
a fastener disposed through the sleeve and penetrating into an adapter plate coupled to a base of the processing chamber; and
adjusting the at least one of the plurality of first leveling units includes installing a shim between a head of the fastener and the sleeve.

13. The method of claim 5, wherein:
the at least one of the plurality of the first leveling units includes:
a sleeve coupled to a frame by a thread; and
a fastener disposed through the sleeve and penetrating into an adapter plate coupled to a base of the processing chamber; and
adjusting the at least one of the plurality of first leveling units includes rotating the sleeve with respect to the frame.

14. A processing chamber, comprising:
a chamber body including a base;
a substrate support disposed within the chamber body, the substrate support including a seal plate disposed below a support plate;
a first shaft coupled to the seal plate, the first shaft extending through the base;
a second shaft coupled to the support plate, the second shaft extending through the base; and
a leveling system, comprising:
an adapter plate coupled to the base;
a frame coupled to the adapter plate by a plurality of first leveling units;
a lift guide coupled to the frame; and
a carrier plate movable along the lift guide between a lowered position and a raised position, the carrier plate coupled to the first shaft.

15. The processing chamber of claim 14, wherein each of the first leveling units includes:
a sleeve coupled to the frame; and
a fastener disposed through the sleeve and penetrating into the adapter plate.

16. The processing chamber of claim 14, wherein the carrier plate is coupled to the first shaft via a seal plate hub.

17. The processing chamber of claim 16, wherein the second shaft extends through the carrier plate, and is coupled to a support plate hub.

18. The processing chamber of claim 17, wherein the support plate hub is coupled to the seal plate hub by a plurality of second leveling units.

19. The processing chamber of claim 18, wherein each of the second leveling units includes:
a sleeve coupled to the support plate hub; and
a fastener disposed through the sleeve and penetrating into the seal plate hub.

20. The processing chamber of claim 18, wherein:
an orientation of the seal plate with respect to a liner assembly of the processing chamber is altered by adjusting one or more of the plurality of first leveling units; and
an orientation of the support plate with respect to a showerhead of the processing chamber is altered by adjusting one or more of the plurality of second leveling units.
